(19) United States
(12) Patent Application Publication
(10) Pub. No.: US 2025/0171634 A1
(43) Pub. Date: May 29, 2025

(54) ELASTIC RESIN COMPOSITION, AND RESIN FILM, RESIN-ATTACHED METAL FOIL, METAL-CLAD LAMINATED SHEET, WIRING BOARD AND CIRCUIT MOUNTED ARTICLE OBTAINED USING SAME

(71) Applicant: PANASONIC INTELLECTUAL PROPERTY MANAGEMENT CO., LTD., Osaka (JP)

(72) Inventors: Kyosuke MICHIGAMI, Tokushima (JP); Tomoaki SAWADA, Osaka (JP)

(73) Assignee: PANASONIC INTELLECTUAL PROPERTY MANAGEMENT CO., LTD., Osaka (JP)

(21) Appl. No.: 19/025,306

(22) Filed: Jan. 16, 2025

Related U.S. Application Data
(63) Continuation of application No. PCT/JP2023/024447, filed on Jun. 30, 2023.

(30) Foreign Application Priority Data
Jul. 25, 2022 (JP) 2022-118023

(51) Int. Cl. C08L 75/04; C08J 5/18; H05K 1/03

(52) U.S. Cl. CPC C08L 75/04; C08J 5/18; H05K 1/0353; C08J 2375/04; C08J 2463/02; C08L 2203/16; C08L 2203/20

(57) ABSTRACT

One aspect of the present invention provided relates to a stretchable resin composition containing a polyrotaxane (A), an epoxy resin (B), and a crosslinking agent (C), in which the crosslinking agent (C) contains an isocyanate compound having two or more isocyanate groups, the isocyanate groups being blocked with imidazole groups.

### FIELD OF INVENTION

The present invention relates to a stretchable resin composition and a resin film, a metal foil with resin, a metal-clad laminate, and a wiring board, which are obtained using the same.

### BACKGROUND ART

Thermosetting resins are used in a wide range of fields such as electronic materials and optical materials because of excellent heat resistance, chemical resistance, formability, insulation reliability, and the like thereof. In particular, as a thermosetting resin, an epoxy resin is often used for various applications. However, it is also known that an epoxy resin is excellent in the above characteristics, but is generally hard and has poor flexibility. Therefore, deformation or breakage may occur due to external stress or thermal stress.

Examples of the material having more excellent flexibility include thermoplastic resins such as silicone resins and urethane resins, and various rubber materials. As for the flexibility of the resin material, not only low elastic modulus and large tensile elongation, but also high recoverability after elongation is required for use in various members.

For example, development of a flexible display device such as electronic paper has been advanced using such a material having excellent flexibility. In general, the electronic paper is formed of a laminate of a display layer for realizing display and a conductive layer for applying a voltage while there are many methods such as an electrophoresis method and a twist ball method. A urethane resin is mainly used for an electrophoretic flexible display device (Patent Literature 1). On the other hand, in the twist ball method, a silicone resin is used (Patent Literature 2).

On the other hand, the characteristics required for recent resin materials together with flexibility include stress relaxation. The urethane resin and the silicone resin as described in Patent Literature 1 or 2 have large tensile elongation and have excellent recoverability, but it is known that this stress relaxation is low. The fact that the residual stress is large when the stress is applied and deformed means that the force to return to an original shape is large. Therefore, when the residual stress is large, peeling or breakage between members occurs.

In order to solve such a conventional problem, it has been proposed to use a resin composition containing a polyrotaxane, an epoxy resin, and a curing agent in order to achieve both recoverability and stress relaxation (Patent Literature 3).

The resin composition described in Literature 3 is useful because it can provide a material which is flexible and has excellent recoverability and stress relaxation after extension. On the other hand, according to studies by the present inventors, it was found that there is room for improvement in storage stability and shortening of curing time in a resin composition containing a polyrotaxane, an epoxy resin, and a curing agent.

In the technique described in Literature 3, it is described that an isocyanate resin or a blocked isocyanate can be used as a crosslinking agent. However, according to further studies by the present inventors, there was found a problem that storage stability tends to be poor when an isocyanate resin is used, and when a blocked isocyanate is used, outgassing due to heating occurs depending on the type of blocking agent, which causes swelling and the like.

The present invention is made in view of such circumstances, and an object of the present invention is to provide a resin composition that can provide a material which is flexible, has excellent recoverability and stress relaxation after extension, and also has excellent storage stability (varnish life) and curing speed, and can suppress generation of outgas, and a film, a laminate, a wiring board, and the like, which are obtained using the same.

Patent Literature 1: JP 2012-63437 A

Patent Literature 2: JP 2012-27488 A

Patent Literature 3: JP 6380942 B2

### SUMMARY OF THE INVENTION

As a result of intensive studies, the present inventors found out that the problems can be solved by a resin composition having the following configuration, and completed the present invention by conducting further studies based on this finding.

That is, a stretchable resin composition according to one aspect of the present invention contains a polyrotaxane (A), an epoxy resin (B), and a crosslinking agent (C), in which the crosslinking agent (C) contains an isocyanate compound having two or more isocyanate groups, the isocyanate groups being blocked with imidazole groups.

### BRIEF DESCRIPTION OF THE DRAWINGS

FIG. 1 is a schematic top view of a single-sided copper wiring board prepared in Example 21.

FIG. 2 is a schematic view showing a preparation process of a single-sided copper wiring board prepared in Example 21.

FIG. 3 is a schematic view of a double-sided copper wiring board prepared in Example 22.

FIG. 4 is a schematic view showing a preparation process of a single-sided silver wiring board prepared in Example 23.

FIG. 5 is a schematic view of a double-sided silver wiring board prepared in Example 24.

FIG. 6 is a schematic top view showing a preparation process of a circuit mounted article prepared in Example 25.

FIG. 7 is a schematic diagram of conductivity tests performed using wiring boards and circuit mounted article prepared in Examples 21 to 25.

### DETAILED DESCRIPTION

Hereinafter, embodiments according to the present invention will be specifically described, but the present invention is not limited thereto.

As described above, the stretchable resin composition (hereinafter, also simply referred to as “the resin composition”) of the present embodiment contains a polyrotaxane (A), an epoxy resin (B), and a crosslinking agent (C), and the crosslinking agent (C) contains an isocyanate compound having two or more isocyanate groups, the isocyanate groups being blocked with imidazole groups.

With such a configuration, the resin composition of the present embodiment has advantages that it is possible to provide a material having excellent flexibility, and recoverability and stress relaxation after extension, and also has excellent storage stability (varnish life) and curing speed, and can suppress generation of outgas.

Therefore, according to the present embodiment, it is possible to provide a resin composition that can provide a material having excellent flexibility, and recoverability and stress relaxation after extension, and also has excellent storage stability (varnish life) and curing speed, and can suppress generation of outgas, and a film, a laminate, a wiring board, and the like, which are obtained using the same.

In the present embodiment, the term “having flexibility” means that the elongation rate (elongation at break) of the cured product of the resin composition of the present embodiment until breakage is 5.0% or more, preferably 10% or more, more preferably 25% or more, still more preferably 50% or more, most preferably 100% or more. In a preferred embodiment, the tensile modulus of a cured product of the resin composition of the present embodiment at room temperature of 25° C. is 0.1 MPa or more and 0.5 GPa or less, preferably 1 MPa or more, more preferably 3 MPa or more, and preferably 300 MPa or less, more preferably 100 MPa or less.

Meanwhile, it is not particularly required to set the upper limit for flexibility, but it is preferable that the elongation rate does not exceed 500% from the viewpoint that the original shape is impaired when the cured product is elongated more than necessary. The index (elongation rate) indicating flexibility in the present embodiment is denoted by the elongation at break [%] in Examples.

First, each component contained in the stretchable resin composition of the present embodiment will be described. In the present embodiment, the resin composition is a composition before curing (uncured or semi-cured) and after curing.

### Polyrotaxane (A)

A polyrotaxane (A) used in the present embodiment is a molecule having a structure in which a linear axial molecule passes through a cyclic molecule and the ends are blocked to prevent the cyclic molecule from coming off. Specifically, examples of the polyrotaxane (A) include polyrotaxane resins such as those described in U.S. Pat. No. 4,482,633.

By containing such a polyrotaxane resin, the resin composition of the present embodiment can have characteristics of excellent repeatability and recoverability when deformed.

Examples of the polyrotaxane that can be used in the present embodiment include a compound in which a molecule having a terminal functional group serving as an axial molecule is included in a cyclic molecule in a skewered state, and this terminal functional group is chemically modified with a blocking group that is sufficiently bulky to prevent detachment of the cyclic molecule. As long as the polyrotaxane has such a structure, the structure and type of the molecule constituting each polyrotaxane, the inclusion ratio of the cyclic molecule, the production method, and the like are not limited.

For example, the axial molecule that can be contained in the polyrotaxane is not particularly limited as long as it has a molecular weight of 8,000 or more and can be chemically modified at the ends with blocking groups, and examples thereof include polyvinyl alcohol, polyvinyl pyrrolidone, poly(meth)acrylic acid cellulose resins, polyacrylamide, polyethylene oxide, polyethylene glycol, polypropylene glycol, polyvinyl acetal resin, polyvinyl methyl ether, polyamine, polyethyleneimine, casein, gelatin, starch, polyolefin, polyester, polyvinyl chloride, polystyrene, copolymers such as acrylonitrile-styrene copolymers, acrylic resins, polycarbonate, polyurethane, polyvinyl butyral, polyisobutylene, polytetrahydrofuran, polyamide, polyimide, polydiene, polysiloxane, polyurea, polysulfide, polyphosphazene, polyketone, polyphenylene, polyhalo-olefins, and derivatives thereof. Among them, polyethylene glycol is suitably used.

In addition, the cyclic molecule that can be contained in the polyrotaxane is not particularly limited as long as it is a cyclic molecule capable of passing a polymer molecule and has at least one reactive group so as to be capable of reacting with a crosslinking agent. Specific examples thereof include cyclodextrins, crown ethers, cryptands, macrocyclic amines, calixarenes, and cyclofans. Among them, cyclodextrins, substituted cyclodextrins, and more preferably those obtained by further introducing a reactive group (functional group) into a substituted structure are used.

Preferred examples of the functional group to be introduced into the cyclic molecule of the polyrotaxane include a hydroxyl group, a carboxyl group, an acrylic group, a methacrylic group, an epoxy group, and a vinyl group. Preferably, the polyrotaxane of the present embodiment has at least one or more reactive hydroxyl groups in the structure. As a result, curability can be controlled by heat curing, and heat resistance can be imparted. In addition, there is an advantage that a tough polymer network is constructed and the breaking strength is improved.

As the polyrotaxane resin of the present embodiment, a polyrotaxane resin having a hydroxyl equivalent of about 300 to 1,000 eq/g is particularly suitable.

The functional group thus introduced into the cyclic molecule can crosslink the cyclic molecules or the polyrotaxane and the resin via the crosslinking agent. Then, the resin connected to the polyrotaxane as described above can acquire flexibility.

The terminal blocking structure (terminal blocking group) in the polyrotaxane of the present embodiment is not particularly limited as long as it is a structure having such a bulkiness that the cyclic molecule does not escape. Specifically, for example, a cyclodextrin group, an adamantane group, a dinitrophenyl group, a trityl group, and the like are preferably used.

The compound used as the cyclic molecule is not particularly limited as long as a chain polymer molecule can be included in the ring. Examples of the cyclic molecule suitably used include cyclodextrin. The cyclic molecule preferably has a functional group. Furthermore, the functional group is preferably a —OH group, an acrylic group, or a methacrylic group.

The polyrotaxane resin that can be used in the present embodiment can be synthesized by a known method (for example, the methods described in WO 2001/83566 A, JP 2005-154675 A, JP 4482633 B2, and the like), but a commercially available polyrotaxane resin may be used, and specifically, SeRM Super Polymers SH3400P, SH2400P manufactured by ASM Inc., and the like can be used.

The molecular weight of the polyrotaxane resin that can be used in the present embodiment is preferably about 100,000 to 1,200,000 g/mol. From the viewpoint of solubility in a solvent, it is still more preferably about 100,000 to 800,000 g/mol.

In the resin composition of the present embodiment, the content of the polyrotaxane (A) is not particularly limited, but is preferably 40 parts by mass or more and 89.9 parts by mass or less, more preferably 40 parts by mass or more and 70 parts by mass or less with respect to 100 parts by mass of the sum of the polyrotaxane (A), the epoxy resin (B), and the crosslinking agent (C). When the blended amount of the polyrotaxane (A) is within this range, there is an advantage that recoverability, flexibility, and extensibility can be secured. The recoverability means a property of returning to an original shape when released from tensile stress. When the blended amount is less than 40 parts by mass, the flexibility and recoverability of the film tend to be poor, and when the blended amount is 90 parts by mass or more, sufficient extensibility may not be secured.

### Epoxy Resin (B)

Specifically, examples of the epoxy resin (B) used in the resin composition of the present embodiment include bisphenol A type epoxy resins, bisphenol F type epoxy resins, bisphenol S type epoxy resins, aralkyl epoxy resins, phenol novolac type epoxy resins, alkylphenol novolac type epoxy resins, biphenol type epoxy resins, naphthalene type epoxy resins, and dicyclopentadiene type epoxy resins. Also, examples of the epoxy resin (B) include epoxidized products of condensates of a phenol and an aromatic aldehyde having a phenolic hydroxyl group, triglycidyl isocyanurate, and alicyclic epoxy resins. These may be used singly or in combination of two or more kinds thereof depending on the situation.

As the epoxy resin, more preferably, for example, an epoxy resin, which contains two or more epoxy groups and three or more methyl groups in one molecule and has a molecular weight of 500 or more, is suitably exemplified. By using such an epoxy resin, there is an advantage that both extensibility and heat resistance can be maintained without further becoming brittle in the cured product of the resin composition.

As such an epoxy resin, a commercially available epoxy resin may be used, and examples thereof include JER1003 (manufactured by Mitsubishi Chemical Corporation, seven to eight methyl groups, bifunctional, molecular weight 1300), EXA-4816 (manufactured by DIC Corporation, many methyl groups, bifunctional, molecular weight 824), and YP50 (manufactured by Nippon Steel & Sumikin Chemical Co., Ltd., many methyl groups, bifunctional, molecular weight 60,000 to 80,000).

One kind of epoxy resin as described above may be used singly, or two or more kinds may be used concurrently.

In the resin composition of the present embodiment, the content of the epoxy resin (B) is not particularly limited, but is preferably 10 parts by mass or more and 60 parts by mass or less, and more preferably 20 parts by mass or more and 50 parts by mass or less with respect to 100 parts by mass of the sum of the polyrotaxane (A), the epoxy resin (B), and the crosslinking agent (C). It is considered that the characteristics such as heat resistance and flexibility of the resin composition can be more reliably obtained by blending the epoxy resin (A) at such a blending ratio. When the content is less than 10 parts by mass, heat resistance and resin extensibility may be deteriorated, and when the content is more than 60 parts by mass, flexibility may be deteriorated.

Furthermore, the resin composition of the present embodiment may contain a resin other than the polyrotaxane (A) and the epoxy resin (B), a urethane resin, an acrylic resin, a fluororesin, and a silicone resin and the like can be further added depending on the purpose.

### Crosslinking Agent (C)

The resin composition of the present embodiment further contains a crosslinking agent (C). The crosslinking agent (C) contains an isocyanate compound having two or more isocyanate groups, the isocyanate groups being blocked with imidazole groups. By containing such an isocyanate compound, the resin composition of the present embodiment has an advantage that it is excellent in storage stability and outgassing is less likely to occur even when heated.

As described above, the isocyanate compound of the present embodiment has two or more isocyanate groups. When the number of isocyanate groups is less than 2, the resin composition is not cured, and curing failure occurs. The number of isocyanate groups is not particularly limited as long as it is two or more, but is preferably 6 or less, more preferably 4 or less, still more preferably 3 or less from the viewpoint of securing the extensibility of the resin.

The isocyanate compound of the present embodiment is a blocked isocyanate, and the isocyanate groups are blocked by imidazole groups. That is, in the blocked isocyanate of the present embodiment, a blocking agent (terminal blocking group) is a compound having an imidazole group. Preferably, in the isocyanate compound of the present embodiment, it is desirable that all isocyanate groups are blocked, but some isocyanate groups may remain in a free (not blocked) state.

In the present embodiment, the compound having an imidazole group is not limited as long as it is a compound having an imidazole structure, but is preferably a compound having a 1H-imidazole group. The compound having a 1H-imidazole group is specifically, for example, a compound represented by the following formula (1):

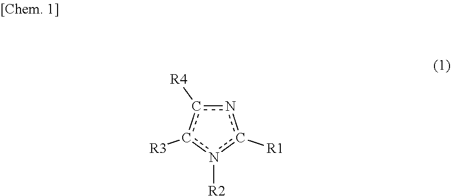

wherein R1 to R3 each independently represent hydrogen, an alkyl group, a phenyl group, cyano, cyanoalkyl, chlorine, or bromine, and R4 is hydrogen.

Examples of such compounds include the following compounds:

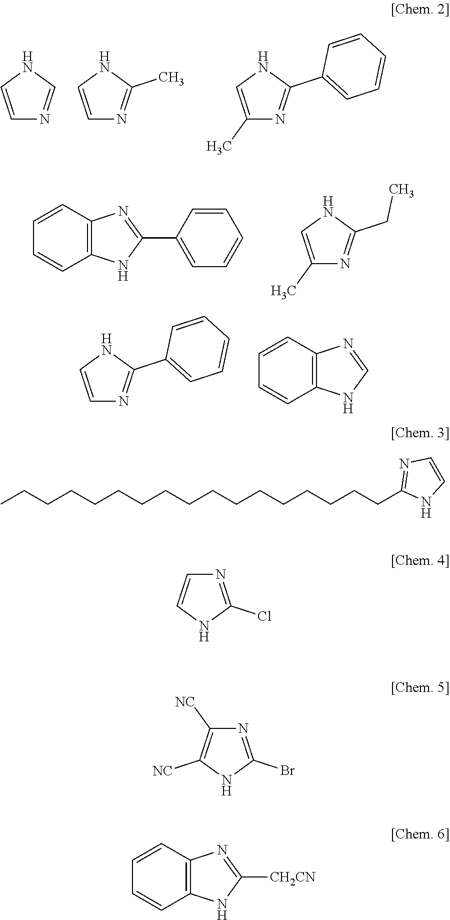

The blocked isocyanate compound used in the present embodiment preferably has a number average molecular weight (hereinafter, in the present specification, it may be simply referred to as “molecular weight”) of 300 or more and 4,000 or less. Thereby, there are advantages that volatilization of the isocyanate component during curing can be suppressed and the curing speed can be further shortened. A more preferable molecular weight range is 400 or more and 3,700 or less.

In the blocked isocyanate compound of the present embodiment, the weight average molecular weight of the isocyanate compound before blocking is preferably 194 or more and 3,400 or less. Thereby, there are advantages that volatilization of the isocyanate component during curing can be further suppressed, and the curing speed can be further shortened.

In addition, the compound having an imidazole group used as a blocking agent has a weight average molecular weight of preferably 68 or more and 310 or less. Thereby, there are advantages that it is easier to react with the epoxy resin (B), and the curing time can be further shortened.

The blocked isocyanate compound of the present embodiment can be produced using an isocyanate compound and a compound having an imidazole group. Specifically, a desired isocyanate compound and a desired compound having an imidazole group can be obtained, for example, by heating in the presence of ethyl acetate. At this time, it is important to perform a reaction of reliably blocking the isocyanate compound as a raw material with an imidazole group by heating or the like. It is noted that storage stability may be degraded if the reaction is not sufficiently performed and an unblocked free isocyanate compound remains.

Alternatively, as the blocked isocyanate compound of the present embodiment, a commercially available product can be used, and for example, “G-8000L” manufactured by DKS Co., Ltd. can be used.

The isocyanate compound may be used singly or in combination of two or more kinds thereof depending on the situation.

In addition, the resin composition of the present embodiment may contain a crosslinking agent other than the above-described blocked isocyanate compound as the crosslinking agent (C) as necessary. The other crosslinking agent is not particularly limited as long as it acts as a crosslinking agent for the thermosetting resin, and examples thereof include a phenol resin, an amine-based compound, an acid anhydride, a sulfide resin, a dicyandiamide, a mercapto-based compound, an onium salt, and a peroxide.

In the resin composition of the present embodiment, the content of the isocyanate compound is not particularly limited, but is preferably 0.5 parts by mass or more and 50.0 parts by mass or less, more preferably 1.0 parts by mass or more and 35.0 parts by mass or less with respect to 100 parts by mass of the sum of the polyrotaxane (A) and the epoxy resin (B). By blending the isocyanate compound at such a blending ratio, it is considered that there are advantages that the above-described effects can be more reliably obtained and flexibility and extensibility can be maintained.

Furthermore, the resin composition according to the present embodiment may contain other additives, for example, a curing accelerator (curing catalyst), a monofunctional isocyanate, a coloring material, a dispersant, a surfactant, a flame retardant, a flame retardant promoter, a leveling agent, a colorant, an antioxidant, a ultraviolet absorber, an infrared absorber, an antistatic agent, a conduction auxiliary, and inorganic fine particles if necessary within a range in which the effects of the present invention is not impaired.

### Curing Accelerator

The curing accelerator usable in the present embodiment is not particularly limited, but for example, imidazoles and derivatives thereof, organophosphorus-based compounds, metal soaps such as zinc octanoate, secondary amines, tertiary amines, sulfonium salts, and quaternary ammonium salts can be used. These may be used singly or in combination of two or more kinds thereof depending on the situation.

When the curing accelerator is used, the content thereof is preferably 0.01 parts by mass or more and 1 part by mass or less with respect to 100 parts by mass of the sum of the polyrotaxane (A), the epoxy resin (B), and the crosslinking agent (C).

### Coloring Material

The resin composition of the present embodiment may further contain a coloring material. By containing a coloring material, the resin composition can be used as a base material further having visibility, designability, and/or concealing properties of intentionally concealing an inner layer core, an electronic component, and the like.

Examples of the coloring material that can be used in the present embodiment include, but are not particularly limited to, carbon black, a pigment, and a dye. As the pigment, either an inorganic pigment or an organic pigment can be used. Examples of the inorganic pigment include titanium oxide, zinc white, zinc sulfide, white lead, calcium carbonate, precipitated barium sulfate, white carbon, alumina white, kaolin clay, talc, bentonite, black iron oxide, cadmium red, red iron oxide, molybdenum red, molybdate orange, chrome vermilion, chrome yellow, cadmium yellow, yellow iron oxide, titanium yellow, chromium oxide, viridian, titanium cobalt green, cobalt green, cobalt chromium green, victoria green, ultramarine blue, prussian blue, cobalt blue, cerulean blue, cobalt silica blue, cobalt zinc silica blue, manganese violet, and cobalt violet.

When the coloring material is contained, the content thereof is not particularly limited, but is preferably about 0.01 parts by mass or more and 10 parts by mass or less, more preferably about 0.1 parts by mass or more and 1.5 parts by mass or less with respect to 100 parts by mass of the sum of the polyrotaxane (A), the epoxy resin (B), and the crosslinking agent (C).

### Dispersant

When the resin composition of the present embodiment contains a coloring material, it is preferable to further add a dispersant for the purpose of improving dispersion stability of the coloring material and the resin component. The dispersant is not particularly limited as long as it is effective as a dispersant, but examples thereof include copolymers containing acid groups, pigment-affinity block copolymers, phosphate ester-based compounds, polyether phosphate ester-based compounds, fatty acid ester-based compounds, alkylene oxide copolymers, modified polyether polymers, fatty acid derivatives, and urethane polymers. Commercially available dispersants include DISPERBYK series manufactured by BYK; SOLSPERSE series manufactured by The Lubrizol Corporation; Sokalan, Tamol, and Efka series manufactured by BASF; Nuosperse series manufactured by Elementis PLC; DISPARLON series manufactured by Kusumoto Chemicals, Ltd.; FLOWLEN series manufactured by KYOEISHA CHEMICAL Co., Ltd.; and AJISPER series manufactured by Ajinomoto Fine-Techno Co., Inc. These may be used singly or in combination of two or more kinds thereof depending on the situation. It is preferable to use the dispersant so that the content thereof is about 10:1 to 2:1 (mass ratio) with respect to the coloring material contained in the resin composition.

### Method for Preparing Resin Composition

The method for preparing the resin composition of the present embodiment is not particularly limited, and for example, the resin composition (varnish-like resin composition) of the present embodiment can be obtained by, first, uniformly mixing the polyrotaxane (A), the epoxy resin (B), the crosslinking agent (C), and a solvent. The solvent to be used is not particularly limited, and for example, toluene, xylene, methyl ethyl ketone, acetone, and ethyl acetate can be used. These solvents may be used singly or in combination of two or more kinds thereof. If necessary, an organic solvent for adjusting the viscosity and various additives may be blended.

The molded article that is a dried product, semi-cured product, or cured product of the resin composition thus obtained can be used as a material for various electronic components in various applications. In particular, since the resin composition has excellent preservation stability, flexibility, and extensibility, and also excellent adhesive properties to a support substrate, a metal foil, and the like, it is very useful for industrial use.

### Resin Film

By applying the resin composition obtained as described above to the film support substrate and heating and drying the resin composition to dry, semi-cure, or cure the resin composition while evaporating the solvent, whereby a resin film can be obtained. That is, the present invention also includes a stretchable resin film formed using the above-described stretchable resin composition. Furthermore, a resin film with a support sheet having a resin layer formed using the above-described stretchable resin composition and a support sheet laminated on at least one surface of the resin layer is also included. The resin layer contains a dried product or semi-cured product of the stretchable resin composition of the present embodiment.

The method for forming the resin film is not particularly limited, and for example, a commonly used coating machine such as spin coating, a bar coater, a comma coater, a die coater, a roll coater, or a gravure coater can be used.

The support sheet (support substrate) used in the resin film of the present embodiment is not particularly limited, and for example, a hard support such as glass, metal, or a printed wiring board may be used, or a support having flexibility and stretchability such as a resin film, a flexible substrate, or an elastomer can be used. Specific examples of the film support substrate include films such as a polyimide film, a PET (polyethylene terephthalate) film, polyethylene naphthalate, a polyester film, a poly (parabanic acid) film, a polyether ether ketone film, a polyphenylene sulfide film, an aramid film, a polycarbonate film, and a polyarylate film.

The method and apparatus for heating and drying, and curing the resin composition and the conditions of these may be the same various units as conventional units or improved units thereof. The specific heating temperature and time can be appropriately set according to a crosslinking agent, a solvent, or the like to be used.

For example, the drying temperature can be selected depending on the solvent to be used, but is preferably set to about 50 to 120° C., and is preferably set around the boiling point of the solvent. The drying time is preferably about 5 minutes to 1 hour as long as the solvent component is volatilized. When the drying temperature is too high, volatilization of the solvent from the coating film occurs rapidly, resulting in poor appearance of the film. When the drying temperature is too low, the solvent component remains, and when increasing the temperature to a high temperature in the next effect step, volatilization of the solvent residual component from the coating film occurs rapidly, resulting in poor appearance.

The curing temperature can be selected depending on the crosslinking agent to be used, but 80 to 220° C. is preferable. Since the crosslinking agent (C) is used in the resin composition of the present embodiment, the curing time for obtaining a desired semi-cured product or cured product is about 5 minutes to 1 hour, and the resin composition can be cured faster than the conventional resin composition.

In the present embodiment, the “semi-cured product” is one in a state where the resin composition is partly cured so as to be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state where the viscosity has started to increase but curing is not completed, and the like.

In the present embodiment, the “dried product” means a resin composition before curing (the resin composition in A stage) in which the solvent is dried.

### Metal Foil With Resin

The metal foil with resin according to the present embodiment includes a resin layer containing a dried product or semi-cured product of the above-described stretchable resin composition, and a metal foil laminated on at least one surface of the resin layer.

Examples of the method for producing such a metal foil with resin include a method in which a resin composition in the form of a varnish as described above is applied to the surface of a metal foil such as a copper foil and then dried. Examples of the coating method include spin coating, a bar coater, a comma coater, a die coater, a roll coater, and a gravure coater.

As the metal foil, metal foils used in metal-clad laminates, wiring boards and the like can be used without limitation, and examples thereof include copper foil and aluminum foil.

### Metal-Clad Laminate

The metal-clad laminate of the present embodiment includes an insulating layer containing a cured product of the above-described stretchable resin composition, and a metal foil laminated on at least one surface of the insulating layer. As the metal foil used in the metal-clad laminate, those the same as the metal foils described above can be used.

In the present embodiment, the “cured product” refers to a state in which the curing reaction has been completed (C-stage) through a process of applying sufficient energy, such as heat or light, for curing to the resin composition.

The metal-clad laminate of the present embodiment can also be fabricated using the metal foil with resin or resin film described above.

Examples of a method for fabricating a metal-clad laminate using the metal foil with resin or the resin film obtained in the manner described above include a method in which a double-sided metal-clad laminate or a single-sided metal-clad laminate is fabricated by stacking one sheet or a plurality of sheets of metal foils with resin or resin films, further stacking the metal foil such as a copper foil on both or one of upper and lower surfaces as necessary, and laminating and integrating them by heating and pressing. The heating and pressing conditions can be appropriately set depending on the thickness of the laminate to be produced, and the kind of the resin composition, and the like, but for example, the temperature may be set to 150 to 220° C., the pressure may be set to 0.05 to 5.0 MPa, and the time may be set to 5 to 150 minutes.

The metal-clad laminate may be fabricated by forming a film-like resin composition on the metal foil without using the metal foil with resin, the resin film, or the like and performing heating and pressing.

### Wiring Board and Circuit Mounted Article

The wiring board of the present embodiment includes an insulating layer containing a cured product of the above-described resin composition, and a wiring formed on at least one surface of the insulating layer.

As the method for producing such a wiring board, for example, the metal foil on the surface of the metal-clad laminate obtained above is etched to form a circuit (wiring), whereby a wiring board having a conductor pattern (conductor wiring) provided as a circuit on the surface of the laminate can be obtained. Examples of the circuit forming method include circuit formation by a semi additive process (SAP) or a modified semi additive process (MSAP) in addition to the method described above.

Alternatively, as another wiring forming method, for example, a wiring can be formed also by printing a paste containing conductive particles. Specific examples of the conductive particles include particles composed of silver, silver-coated copper (including a configuration in which a part of the surface of copper is coated with silver), copper, gold, carbon particles, carbon nanotubes, a conductive polymer, tin, bismuth, indium, gallium, or an alloy of these metals. Preferable examples thereof include stretchable epoxy resins, acrylic resins, urethane resins, silicone resins, fluororesins, styrene-butadiene copolymer resins, and silver pastes and silver inks obtained by combining with silver powder, silver flakes, and the like.

Using such a paste or ink, for example, a wiring can be formed by a printing method or the like. Specifically, a wiring having a desired pattern can be formed by printing and applying a conductive paste or a liquid metal containing the conductive particles as described above on the insulating layer by a printing method such as screen printing, inkjet printing, gravure printing, or offset printing.

The wiring formation by etching the above-described metal foil and the wiring formation by printing using a conductive paste or the like may be used in combination. For example, a land portion may be first formed on the insulating layer using the metal-clad laminate as described above, and then a conductive paste may be printed to form a wiring (circuit) pattern connected to the land portion.

Further, the present embodiment also includes a circuit mounted article in which an electronic component is mounted on the above-described wiring board. Specific electronic component that can be mounted is not particularly limited, and examples thereof include wireless modules such as resistances, transistors, signal transmission elements, light emitting elements, solar power generation elements, diodes, switching elements, capacitors, coils, liquid crystals, and Bluetooth (registered trademark), various sensors such as acceleration sensors, humidity sensors, and temperature sensors, chip parts to be used for RFIDs and the like.

As described above, the film with resin and the metal foil with resin obtained using the stretchable resin composition of the present embodiment have not only good storage (preservation) stability but also flexibility and extensibility in a cured product thereof, and thus are extremely useful in industrial applications. The metal-clad laminate and the wiring board obtained by curing them also have both flexibility and extensibility. Further, since the curing time is short and the generation of outgas can be suppressed even when curing is performed by heating, there is also an advantage that a defective product due to swelling or the like is hardly produced.

This specification discloses techniques in various aspects as described above, and the main techniques among them are summarized below.

A stretchable resin composition according to a first aspect of the present invention contains a polyrotaxane (A), an epoxy resin (B), and a crosslinking agent (C), in which the crosslinking agent (C) contains an isocyanate compound having two or more isocyanate groups, the isocyanate groups being blocked with imidazole groups.

A stretchable resin composition according to a second aspect is the stretchable resin composition of the first aspect, in which a content of the isocyanate compound is 0.5 parts by mass or more and 50 parts by mass or less with respect to 100 parts by mass of a sum of the polyrotaxane (A) and the epoxy resin (B).

A stretchable resin composition according to a third aspect is the stretchable resin composition according to the first or second aspect, in which the isocyanate compound has a number average molecular weight of 300 or more and 4,000 or less.

A stretchable resin composition according to a fourth aspect is the stretchable resin composition according to any one of the first to third aspects, in which the imidazole group is a 1H-imidazole group.

A stretchable resin composition according to a fifth aspect is a stretchable resin composition according to any one of the first to fourth aspects, in which the stretchable resin composition when formed into a cured product has an elongation at break of 100% or more.

A stretchable resin composition according to a sixth aspect is the stretchable resin composition according to any one of the first to fifth aspects, in which the epoxy resin (B) contains an epoxy resin containing two or more epoxy groups and three or more methyl groups in one molecule and having a molecular weight of 500 or more.

A stretchable resin composition according to a seventh aspect is the stretchable resin composition according to any one of the first to sixth aspects further including a coloring material.

A stretchable resin film according to an eighth aspect is formed using the stretchable resin composition according to any one of the first to seventh aspects.

A stretchable resin film with a support sheet according to a ninth aspect has the stretchable resin film according to the eighth aspect, and a support sheet laminated on at least one surface of the stretchable resin film.

A metal foil with resin according to a tenth aspect includes a resin layer containing a dried product or semi-cured product of the stretchable resin composition according to any one of the first to seventh aspects, and a metal foil laminated on at least one surface of the resin layer.

A metal-clad laminate according to an eleventh aspect includes an insulating layer containing a cured product of the stretchable resin composition according to any one of the first to seventh aspects, and a metal foil laminated on at least one surface of the insulating layer.

A wiring board according to a twelfth aspect includes an insulating layer containing a cured product of the stretchable resin composition according to any one of the first to seventh aspects, and a wiring formed on at least one surface of the insulating layer.

In a circuit mounted article according to a thirteenth aspect, an electronic component is mounted on the wiring board according to the twelfth aspect.

Hereinafter, the present invention will be described more specifically with reference to Examples, but the scope of the present invention is not limited thereto.

### EXAMPLES

First, all kinds of materials used in the present Examples are as follows.

### Polyrotaxane (A)

Polyrotaxane: “SH3400P” manufactured by ASM Inc. (using PEG as an axial molecule, α-cyclodextrin as a cyclic molecule, and having an OH group as a reactive group), hydroxyl value 72 mgKOH/g, hydroxyl equivalent 779

### Epoxy Resin (B)

Epoxy resin: “JER1003” manufactured by Mitsubishi Chemical Corporation (bisphenol A epoxy resin, molecular weight 1300, epoxy equivalent 650, seven to eight methyl groups, bifunctional)

### Crosslinking Agent (C)

Isocyanates and imidazoles used for production of the following crosslinking agent (C) are as follows:

### Isocyanates

“DN-950” manufactured by DIC Corporation, polyfunctional isocyanate (three isocyanate groups, molecular weight 1050, isocyanate equivalent 350)
“1,3-Bis(isocyanatomethyl)cyclohexane” manufactured by Tokyo Chemical Industry Co., Ltd. (two isocyanate groups, molecular weight 194.2)
“CORONATE 4076” manufactured by Tosoh Corporation (two isocyanate groups, molecular weight 3384)
“Cyclohexyl isocyanate” manufactured by Tokyo Chemical Industry Co., Ltd. (one isocyanate group, molecular weight 125.2)

### Imidazoles

“2E4MZ” manufactured by Shikoku Chemicals Corporation, 2-ethyl-4-methylimidazole (molecular weight 110.2)
“Imidazole” manufactured by Tokyo Chemical Industry Co., Ltd. (molecular weight 68)
“2-Heptadecylimidazole” manufactured by Tokyo Chemical Industry Co., Ltd. (molecular weight 306.5)
“1,4-Diisocyanatobutane” manufactured by FUJIFILM Wako Pure Chemical Corporation (molecular weight 140.1)

### Production Example 1

Into a pressurized reaction vessel, 100 parts by mass of “DN-950”, 24.7 parts by mass of 2-ethyl-4-methylimidazole “2E4MZ”, and 75 parts by mass of ethyl acetate were charged, heated at 75° C. for 2 hours, and cooled to room temperature to obtain a solution of blocked isocyanate 1 blocked with an imidazole group.

### Production Examples 2 to 5, Comparative Production Examples

Solutions of blocked isocyanates 2 to 6 were obtained in the same manner as in Production Example 1 except that the isocyanates and imidazoles used and the blended amounts thereof were changed as shown in Table 1.

The molecular weights of the obtained blocked isocyanates are also shown in Table 1.

TABLE 1

| | | | Molecular |
|---|---|---|---|
| | Isocyanate | Imidazole | weight |
| Production | DN-950 (100 parts) | 2E4MZ (24.7 parts) | 1386 |
| Example 1 | | | |
| Production | 1,3-Bis(isocyanato- | 2E4MZ (24.7 parts) | 414.23 |
| Example 2 | methyl)cyclo- | | |
| | hexane (43.6 parts) | | |
| Production | DN-950 (100 parts) | Imidazole (19.3 parts) | 1260 |
| Example 3 | | | |
| Production | DN-950 (100 parts) | 2-Heptadecylimidazole | 1975.5 |
| Example 4 | | (68.9 parts) | |
| Production | Coronate 4076 | 2E4MZ (23.6 parts) | 3604.6 |
| Example 5 | (380.2 parts) | | |
| Production | Cyclohexyl isocyanate | 2E4MZ (23.6 parts) | 455.17 |
| Example 6 | (28.1 parts) | | |

The following commercially available isocyanate compounds were also used.
“G-8009L” manufactured by DKS Co., Ltd. (imidazole-blocked isocyanate, mixture of bifunctional and trifunctional, molecular weight 837)
“TPA-B80E” manufactured by Asahi Kasei Corporation (methyl ethyl ketoxime-blocked isocyanate, NCO content 6.0%)

### Coloring Materials and Others

Carbon black: “Carbon Black No. 52” manufactured by Mitsubishi Chemical Corporation
Cyan pigment: “Heliogen Blue D7079” manufactured by BASF Japan Ltd.
Cyan dye: “Direct Blue 86” manufactured by Tokyo Chemical Industry Co., Ltd.
Dispersant: “BYK-9076” manufactured by BYK Additives & Instruments
Curing accelerator: Imidazole-based curing accelerator (“2E4MZ” manufactured by SHIKOKU CHEMICALS CORPORATION, 2-ethyl-4-methylimidazole)

### Test Example

### Examples 1 to 14 and Comparative Examples 1 to 3

Resin varnishes having a concentration of 50 mass % (Examples 1 to 14 and Comparative Examples 1 to 3) were prepared by dissolving them in a solvent (MEK) under stirring at the blended composition presented in Table 2 (in the table, the numerical value of each component indicates parts by mass of the solid content excluding the solvent).

After being left to stand and defoamed, using a release-treated PET film (“SP-PET O1” manufactured by Mitsui Chemicals Tohcello, Inc.) as a support sheet, each of the resin varnishes was applied thereon using a bar coater. Then, the film was dried in an oven at 80° C. for 10 minutes to obtain a dried film (uncured) composed of a dried product of the resin composition. Further, a release-treated PET film (“SP-PET O1” manufactured by Mitsui Chemicals Tohcello, Inc.) was bonded to the dried film to obtain a protected dry resin film in which the dried film (resin layer) was protected.

Separately, the dried film was heated at 160° C. for 5 minutes to obtain a semi-cured film composed of a semi-cured product of the resin composition. Furthermore, a release-treated PET film (“SP-PET O1” manufactured by Mitsui Chemicals Tohcello, Inc.) was bonded to the semi-cured film to obtain a protected semi-cured resin film in which a resin layer containing a semi-cured product of the resin was protected.

Further, separately, the dried resin film was heated in an oven at 160° C. to obtain a cured resin film composed of a cured product of the resin composition.

### Example 15

“Carbon Black No. 52” was added so as to be 0.1 mass % with respect to the solid content of the resin varnish having a concentration of 50 wt % obtained in Example 1, and a dispersant “BYK-9076” was added so as to be 50 mass % with respect to the added carbon black, and the mixture was mixed and kneaded with a three-roll mill to obtain a black varnish. Subsequently, a dry resin film, a protected dry resin film, a semi-cured resin film, a protected semi-cured resin film, and a cured resin film were obtained in the same manner as in the method described in Example 1.

### Example 16

Pigment Blue 15:3 (“Heliogen Blue D7079”) as a cyan pigment was added so as to be 1.0 wt % with respect to the solid content of the resin varnish having a concentration of 50 wt % obtained in Example 1, and a dispersant “BYK-9076” was added so as to be 50 mass % with respect to the added cyan pigment, and the mixture was mixed and kneaded with a three-roll mill to obtain a blue resin varnish. Subsequently, a dry resin film, a protected dry resin film, a semi-cured resin film, a protected semi-cured resin film, and a cured resin film were obtained in the same manner as in the method described in Example 1.

### Example 17

“Direct Blue 86” as a cyan dye was added so as to be 0.1 wt % with respect to the solid content of the resin varnish having a concentration of 50 wt % obtained in Example 1, and the mixture was mixed and kneaded by a disperser (Homodisper model 2.5, manufactured by PRIMIX Corporation) to obtain a blue resin varnish. Subsequently, a dry resin film, a protected dry resin film, a semi-cured resin film, a protected semi-cured resin film, and a cured resin film were obtained in the same manner as in the method described in Example 1.

TABLE 2

| | | Examples | | | | | | | | | |
|---|---|---|---|---|---|---|---|---|---|---|---|
| | | 1 | 2 | 3 | 4 | 5 | 6 | 7 | 8 | 9 | 10 |
| Polyrotaxane (A) | SH3400P | 52.0 | 52.0 | 52.0 | 80.0 | 80.0 | 50.0 | 52.0 | 52.0 | 52.0 | 52.0 |
| Epoxy resin (B) | JER1003 | 48.0 | 48.0 | 48.0 | 20.0 | 20.0 | 50.0 | 48.0 | 48.0 | 48.0 | 48.0 |
| Crosslinking agent | Production Example 1 Blocked isocyanate 1 | 1.9 | 15.4 | 15.4 | 47.4 | 14.2 | 1.0 | | | | |
| (C): Blocked | Production Example 2 Blocked isocyanate 2 | | | | | | | 4.1 | | | |
| isocyanate | Production Example 3 Blocked isocyanate 3 | | | | | | | | 5.8 | | |
| | Production Example 4 Blocked isocyanate 4 | | | | | | | | | 8.8 | |
| | Production Example 5 Blocked isocyanate 5 | | | | | | | | | | 24.1 |
| | Blocked isocyanate G8009L | | | | | | | | | | |
| Other isocyanate | Blocked isocyanate TPA-B80B (HC1) | | | | | | | | | | |
| | Production Example 6 Blocked isocyanate 6 | | | | | | | | | | |
| | Isocyanate DN-950 | | | | | | | | | | |
| Coloring material | Carbon Black No. 52 | | | | | | | | | | |
| | Heliogen Blue D7079 | | | | | | | | | | |
| | Direct Blue 86 | | | | | | | | | | |
| Additional | BYK-9076 | | | | | | | | | | |
| component | Imidazole 2E4MZ | 0.5 | 0.5 | 0.0 | 0.5 | 0.5 | 0.5 | 0.5 | 0.5 | 0.5 | 0.5 |
| | | | | | | | | | Comparative | | |
| | | Examples | | | | | | | Examples | | |
| | | 11 | 12 | 13 | 14 | 15 | 16 | 17 | 1 | 2 | 3 |
| Polyrotaxane (A) | SH3400P | 52.0 | 52.0 | 54.0 | 63.0 | 52.0 | 52.0 | 52.0 | 52.0 | 52.0 | 52.0 |
| Epoxy resin (B) | JER1003 | 48.0 | 35.0 | 23.0 | 27.0 | 48.0 | 48.0 | 48.0 | 48.0 | 48.0 | 48.0 |
| Crosslinking agent | Production Example 1 Blocked isocyanate 1 | | | | | 6.2 | 6.2 | 6.2 | | | |
| (C): Blocked | Production Example 2 Blocked isocyanate 2 | | | | | | | | | | |
| isocyanate | Production Example 3 Blocked isocyanate 3 | | | | | | | | | | |
| | Production Example 4 Blocked isocyanate 4 | | | | | | | | | | |
| | Production Example 5 Blocked isocyanate 5 | | | | | | | | | | |
| | Blocked isocyanate G8009L | 1.4 | 10.2 | 23.0 | 9.9 | | | | | | |
| Other isocyanate | Blocked isocyanate TPA-B80B (HC1) | | | | | | | | 9.3 | | |
| | Production Example 6 Blocked isocyanate 6 | | | | | | | | | 3.1 | |
| | Isocyanate DN-950 | | | | | | | | | | 4.7 |
| Coloring material | Carbon Black No. 52 | | | | | 0.12 | | | | | |
| | Heliogen Blue D7079 | | | | | | 1.2 | | | | |
| | Direct Blue 86 | | | | | | | 0.12 | | | |
| Additional | BYK-9076 | | | | | 0.06 | 0.6 | | | | |
| component | Imidazole 2E4MZ | 0.5 | 0.5 | 0.5 | 0.5 | 0.5 | 0.5 | 0.5 | 0.5 | 0.5 | 0.5 |

### Evaluation Test

### Storage Stability Test

In a 30 ml glass bottle, 15 ml of each of the resin varnishes obtained in Examples 1 to 17 and Comparative Examples 1 to 3 was put and sealed. The glass bottle was allowed to stand at 20° C., and the presence or absence of fluidity was visually confirmed. The criteria for determining varnish life are as follows.
No fluidity at 24 hours: “F” (failed)
Retained fluidity for 24 or more: “P” (passed)

### Tensile Stress at 50% Elongation and Elongation at Break

First, a test piece was prepared. Specifically, size 6 dumbbell test pieces specified in JIS K 6251 were taken from the cured films obtained in Examples 1 to 17 and Comparative Examples 1 and 3. In Comparative Example 2, the film was not cured, and a test piece could not be taken.

Next, each of the obtained test pieces was subjected to a tensile test under the following conditions using an Autograph (AGS-X) manufactured by Shimadzu Corporation.
Load cell: 50N
Initial distance between grippers: 35 mm
Tensile speed: 25 mm/min

As the tensile stress (MPa) at 50% elongation, the stress at the time when the stroke reached 17.5 mm was measured.

$$Stress = \text{} F \text{} / \text{} ( d \cdot 1 ) \text{} ( F is test force , d is film thickness , and 1 is width of test piece )$$

The elongation at break (%) of the film was calculated by the following equation using the moving distance of the gripper at the time of fracture.

$$Elongation at break ( \% ) of film = x / 35 \times 100$$

In this evaluation test, a range of the tensile stress of 0.1 MPa or more and 10 MPa or less is regarded as pass. In addition, an elongation at break (%) of 50% or more is regarded as pass.

### Curing Time

The dried films of Examples 1 to 17 and Comparative Examples 1 to 3 were heated at 160° C., and samples were taken out every 5 minutes. The tensile stress at 50% elongation of the samples was measured, and the time when the change rate was 10% or less was taken as the curing time of each sample. In Comparative Example 2 alone, curing failure remained even after 60 minutes.

### Outgas

In the evaluation test of the curing time, a PET film was laminated on the surface of the film with a support sheet (PET film) after the lapse of the curing time, and the end was sealed with a polyimide tape. Each of the obtained samples was further heated at 160° C. for 30 minutes, and the presence or absence of swelling was visually confirmed. The sample with swelling was determined to have outgas, and the sample without swelling was determined to have no outgas.

The above results are summarized in Table 3.

TABLE 3

| | | Examples | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Evaluation | Varnish life | P | P | P | P | P | P | P | P | P | P | P |
| results | (storage stability) | | | | | | | | | | | |
| | Curing time (min) | 30 | 15 | 15 | 10 | 15 | 30 | 30 | 20 | 55 | 50 | 55 |
| | 50% Stress (Mpa) | 3 | 5 | 4 | 4 | 1 | 3 | 2 | 2 | 1 | 1 | 3 |
| | Elongation at break (%) | 190 | 165 | 180 | 120 | 140 | 180 | 140 | 170 | 100 | 260 | 190 |
| | Outgas | No | No | No | No | No | No | No | No | No | No | No |

| | | Examples | | | | | | Comparative Examples | | |
|---|---|---|---|---|---|---|---|---|---|---|
| | | 12 | 13 | 14 | 15 | 16 | 17 | 1 | 2 | 3 |
| Evaluation | Varnish life | P | P | P | P | P | P | P | P | F |
| results | (storage stability) | | | | | | | | | |
| | Curing time (min) | 20 | 15 | 30 | 30 | 30 | 30 | 60 | Curing | 60 |
| | | | | | | | | | failure | |
| | | | | | | | | | after 60 | |
| | | | | | | | | | minutes | |
| | 50% Stress (Mpa) | 5 | 4 | 1 | 2.1 | 2 | 2 | 7.9 | — | 8.4 |
| | Elongation at break (%) | 170 | 100 | 130 | 190 | 190 | 190 | 195 | — | 180 |
| | Outgas | No | No | No | No | No | No | Yes | No | No |

### Discussion

As is apparent from the results in Table 3, in Examples in which the resin composition of the present invention was used, the storage stability of the varnish was good, the curing time was short, and the generation of outgas during heating could be suppressed, in addition to the good flexibility and the good recoverability at the time of elongation. On the other hand, in Comparative Example 1 in which a blocked isocyanate blocked with a group other than an imidazole group was used as the crosslinking agent (C), outgassing due to heating occurred. Also, in Comparative Example 2 using only a monofunctional (one isocyanate group) blocked isocyanate, curing of the resin composition was insufficient even after a lapse of 60 minutes, and a film could not be formed. Further, in Comparative Example 3 using unblocked isocyanate, it was shown that the resin varnish gelled within 24 hours, and the storage stability was poor.

Furthermore, comparison of Examples 1 to 6 and Examples 11 to 14 showed that the resin composition containing the crosslinking agent (C) in a certain amount or more can further shorten the curing time. Moreover, comparison of Examples 7 to 10 showed that there is also a preferred range of the molecular weight of the crosslinking agent (C). That is, it is considered that the curing time can be further shortened when the molecular weight of the crosslinking agent (C) is in a preferred range.

### Test Example 2

Next, a copper foil with resin, a metal-clad laminate, a wiring board, a circuit mounted article, and the like were produced using the resin composition of the present invention. In addition, with respect to the prepared wiring board and circuit mounted article, a test was also performed as to whether or not conductivity at the time of elongation can be obtained.

### Example 18: Single-Sided Copper Foil With Resin, Single-Sided Copper Foil With Semi-Cured Resin, and Metal-Clad Laminate

The same operation as in Example 1 was performed except that the release-treated PET film (“SP-PET O1” manufactured by Mitsui Chemicals Tohcello, Inc.) was changed to a 12 μm-thick copper foil (“CF-T9DA-SV”, manufactured by Fukuda Metal Foil & Powder Co., Ltd.) to obtain a single-sided copper foil with resin having a resin layer composed of a dried product of the resin composition on one surface, a single-sided copper foil with semi-cured resin having a resin layer composed of a semi-cured product of the resin composition on one surface, and a metal-clad laminate having an insulating layer composed of a cured product of the resin composition on one surface.

Further, the release-treated PET film (“SP-PET O1” manufactured by Mitsui Chemicals Tohcello, Inc.) was bonded to obtain a single-sided copper foil with resin (protected), a single-sided copper foil with semi-cured resin (protected), and a metal-clad laminate (protected) in which the respective resin layers were protected.

### Example 19: Double-Sided Copper Foil With Semi-Cured Resin

A 12 μm-thick copper foil (“CF-T9DA-SV”, manufactured by Fukuda Metal Foil & Powder Co., Ltd.) was bonded to the resin layer side of the single-sided semi-cured resin film obtained in Example 1 using a vacuum laminator to obtain a single-sided copper foil with semi-cured resin having a copper foil layer on both surfaces, in which the intermediate layer was a resin layer composed of a semi-cured product of the resin composition. The temperature of the vacuum laminator was 50° C., the depressurization condition was at 1 hPa for 20 seconds, and the pressurization condition was at 0.3 MPa for 60 seconds. Further, heating was performed at 160° C. for 30 minutes to obtain a single-sided metal-clad laminate in which the intermediate layer was a cured product of the resin composition.

### Example 20: Double-Sided Copper Foil With Semi-Cured Resin and Double-Sided Metal-Clad Laminate

A 12 μm-thick copper foil (“CF-T9DA-SV”, manufactured by Fukuda Metal Foil & Powder Co., Ltd.) was bonded to the resin layer side of the single-sided copper foil with semi-cured resin obtained in Example 18 using a vacuum laminator to obtain a double-sided copper foil with semi-cured resin having a copper foil layer on both surfaces, in which the intermediate layer was a resin layer composed of a semi-cured product of the resin composition. The temperature of the vacuum laminator was 50° C., the depressurization condition was at 1 hPa for 20 seconds, and the pressurization condition was at 0.3 MPa for 60 seconds. Further, the obtained double-sided copper foil with semi-cured resin was heated at 160° C. for 25 minutes to obtain a double-sided metal-clad laminate having a copper foil layer on both surfaces, in which the intermediate layer was a cured product of the resin composition.

### Example 21: Single-Sided Copper Wiring Board

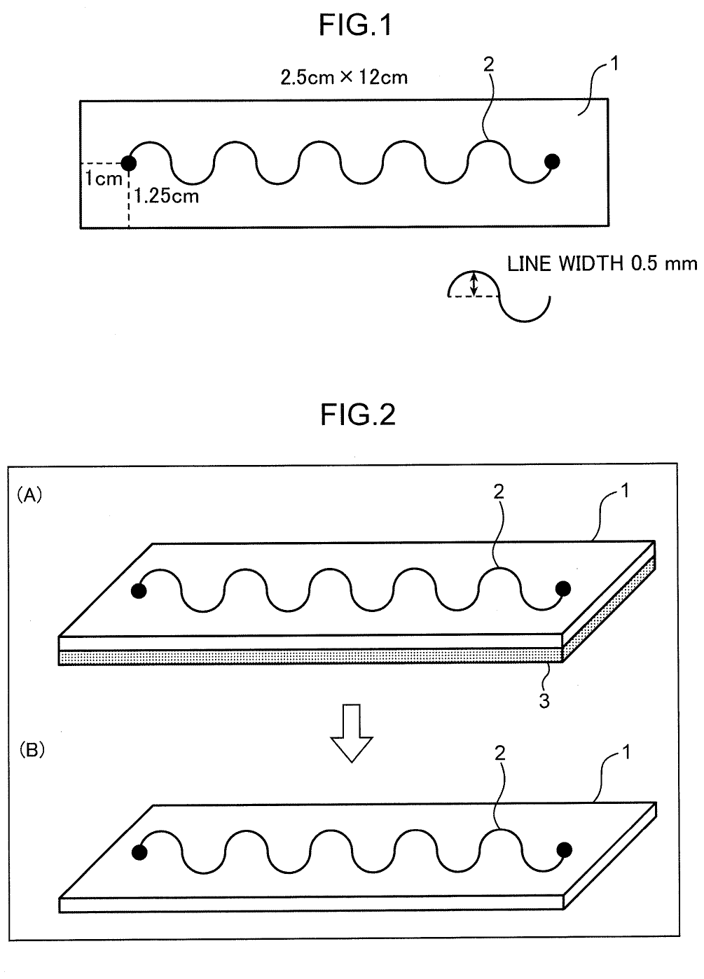

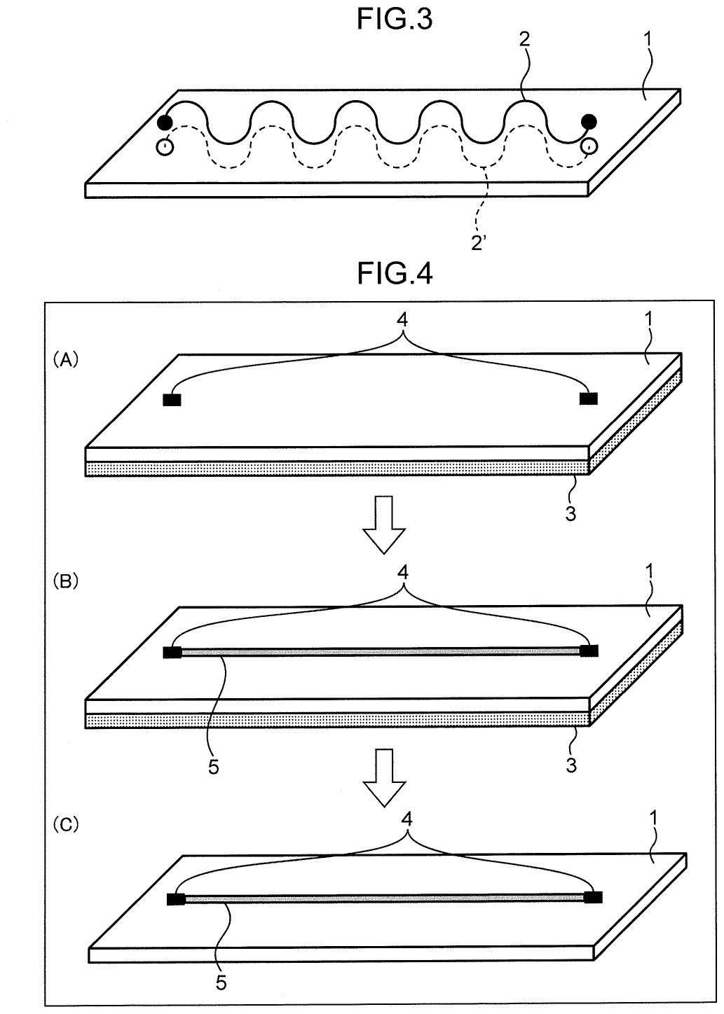

The copper foil with protected single-sided cured resin obtained in Example 18 was cut into a rectangular shape of 12 cm×2.5 cm, a dry film resist was laminated on the copper foil surface, development was performed by photolithography, copper foil etching was performed, a wiring 2 was formed on a resin layer 1 in the pattern (line width: 0.5 mm) shown in FIG. 1, and then a PET film (protective layer) 3 was peeled off to obtain a wiring board (FIGS. 2(A) and 2(B)).

### Example 22: Double-Sided Copper Wiring Board

The double-sided metal-clad laminate obtained in Example 20 was cut into a rectangular shape of 12 cm×2.5 cm, a dry film resist was laminated on the copper foil surfaces on both surfaces, development was performed by photolithography, and copper foil etching was performed to obtain a double-sided wiring board having wirings 2 and 2′ having a pattern shown in FIG. 3 on both surfaces of the resin layer 1.

### Example 23: Silver Wiring Board

The protected metal-clad laminate obtained in Example 18 was cut into a rectangular shape of 15 cm×2.5 cm, a dry film resist was laminated on the copper foil surface, development was performed by photolithography, and copper foil etching was performed to obtain a circuit board in which a copper foil land 4 (0.5 cm×0.5 cm, thickness 12 μm) was formed on the copper foil surface in the pattern shown in FIG. 4(A). Subsequently, a silver nano paste (“PE873” manufactured by Dupont) was printed with a width of 1 mm and a length of 130 mm using a screen plate, and after the printing, the silver nano paste was cured at 150° C. for 10 minutes to obtain a stretchable silver wiring 5 (FIG. 4(B)). Thereafter, a PET film 3 (protective layer) was peeled off to obtain a wiring board (FIG. 4(C)).

### Example 24: Silver Wiring Board

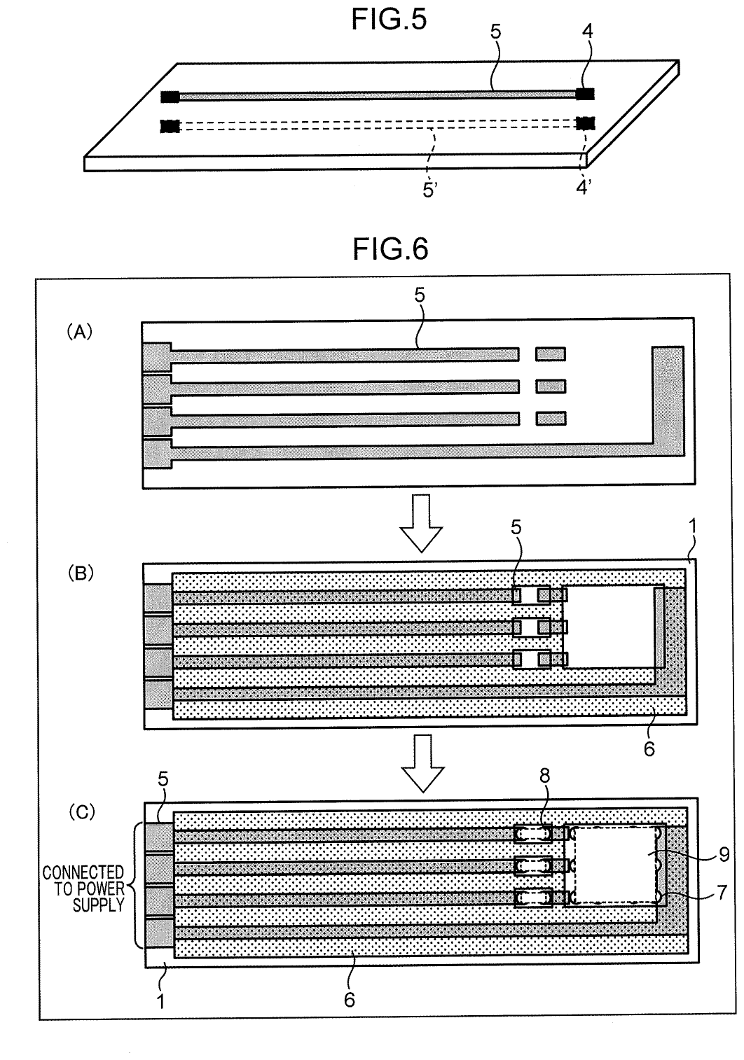

The double-sided metal-clad laminate obtained in Example 20 was cut into a rectangular shape of 15 cm×2.5 cm, a dry film resist was laminated on one surface, development was performed by photolithography, and copper foil etching was performed to obtain a circuit board in which a copper foil land (0.5 cm×0.5 cm, thickness 12 μm) was formed in the pattern shown in FIG. 4(A) on the copper foil surfaces on both surfaces. Subsequently, a silver nano paste (PE873 manufactured by Dupont) was printed using a screen plate, and then cured at 150° C. for 10 minutes. Next, a dry film resist was also laminated on the copper foil on the opposite surface, and development was performed by photolithography, and etched in the pattern shown in FIG. 4(A) by copper foil etching. Thereafter, a silver paste (“PE873” manufactured by Dupont) was printed with a width of 1 mm and a length of 130 mm using a screen plate, and then cured at 150° C. for 10 minutes to obtain a wiring board having stretchable silver wirings 5 and 5′ on both surfaces (FIG. 5).

### Example 25: Circuit Mounted Article

The PET film (protective layer) of the cured resin film obtained in Example 1 was peeled off, and a silver paste (PE873 manufactured by Dupont) was printed using a screen plate and then cured at 150° C. for 10 minutes to obtain a stretchable silver wiring 5 (FIG. 6(A)). Next, a semi-cured film 6 cut into a rectangular shape of 6 cm×3.5 cm and perforated on a mounting portion was laminated using a vacuum laminator, and heated at 160° C. for 30 minutes (FIG. 6(B)). A LED chip 9 and a chip resistor 8 were mounted on the wiring part via a conductive adhesive 7 (“DOTITE D-362” manufactured by Fujikura Kasei Co., Ltd.). Finally, the PET film (support sheet, not shown) was peeled off to obtain a circuit mounted article (FIG. 6(C)).

### Evaluation Test

### Conductivity Test During Stretching

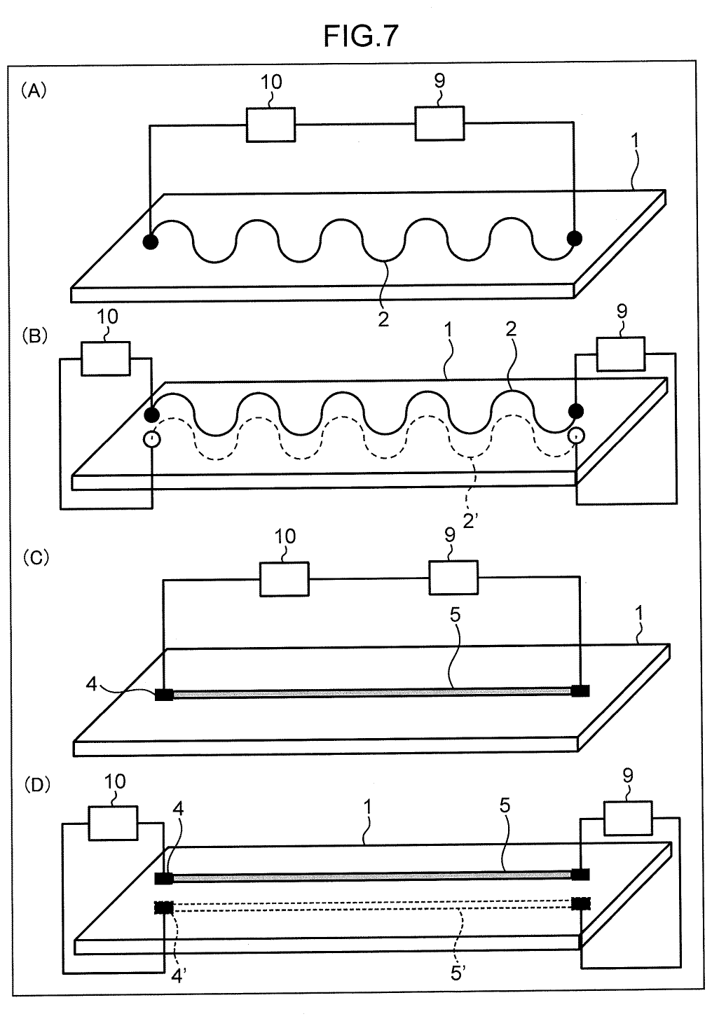

The wiring boards prepared in Examples 21 to 24 were each connected to a battery and a LED as shown in FIG. 7(A) (Example 21), FIG. 7(B) (Example 22), FIG. 7(C) (Example 23), and FIG. 7(D) (Example 24), and lighting of the LED at the time of non-elongation was confirmed. Copper foil lands and wirings were connected by soldering. The circuit mounted article prepared in Example 25 was connected to a power supply, and lighting of the LED at the time of non-elongation was confirmed.

Subsequently, the wiring boards and the circuit mounted article of Examples 21 to 25were fixed to a high accuracy automatic stage, elongated 20% in the long side direction, and it was confirmed that the LED was lit. Finally, it was confirmed that the LED was lit even when the elongation was returned to 0% and continued.

This application is based on Japanese Patent Application No. 2022-118023 filed on Jul. 25, 2022, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

The present invention has wide industrial applicability in various technical fields such as optics, electronics, bonding, and medical treatment.

1. A stretchable resin composition comprising a polyrotaxane (A), an epoxy resin (B) and a crosslinking agent (C),
wherein the crosslinking agent (C) contains an isocyanate compound having two or more isocyanate groups, the isocyanate groups being blocked with imidazole groups.

2. The stretchable resin composition according to claim 1, wherein a content of the isocyanate compound is 0.5 parts by mass or more and 50 parts by mass or less with respect to 100 parts by mass of a sum of the polyrotaxane (A) and the epoxy resin (B).

3. The stretchable resin composition according to claim 1, wherein the isocyanate compound has a number average molecular weight of 300 or more and 4,000 or less.

4. The stretchable resin composition according to claim 1, wherein the imidazole group is a 1H-imidazole group.

5. The stretchable resin composition according to claim 1, wherein the epoxy resin (B) contains an epoxy resin containing two or more epoxy groups and three or more methyl groups in one molecule and having a molecular weight of 500 or more.

6. The stretchable resin composition according to claim 1, wherein the stretchable resin composition when formed into a cured product has an elongation at break of 100% or more.

7. The stretchable resin composition according to claim 1, comprising a coloring material.

8. A stretchable resin film formed using the stretchable resin composition according to claim 1.

9. A stretchable resin film with a support sheet, comprising:
the stretchable resin film according to claim 8; and
a support sheet laminated on at least one surface of the stretchable resin film.

10. A metal foil with resin, comprising:
a resin layer containing a dried product or semi-cured product of the stretchable resin composition according to claim 1; and
a metal foil laminated on at least one surface of the resin layer.

11. A metal-clad laminate comprising:
an insulating layer containing a cured product of the stretchable resin composition according to claim 1; and
a metal foil laminated on at least one surface of the insulating layer.

12. A wiring board comprising:
an insulating layer containing a cured product of the stretchable resin composition according to claim 1; and
a wiring formed on at least one surface of the insulating layer.

13. A circuit mounted article in which an electronic component is mounted on the wiring board according to claim 12.
